(19) United States
(12) Patent Application Publication
(10) Pub. No.: US 2026/0243254 A1
(43) Pub. Date: Aug. 20, 2026

(54) ACTIVE COOLING OF SPECIALLY COATED ECU/PCBA IN ELECTRIC TRANSMISSION OIL PUMP

(71) Applicant: Hanon Systems EFP CANADA LTD, Concord (CA)

(72) Inventors: Harpreet Singh, Concord (CA); Matthew Williamson, Concord (CA)

(21) Appl. No.: 19/407,632

(22) Filed: Dec. 3, 2025

Related U.S. Application Data
(60) Provisional application No. 63/758,736, filed on Feb. 14, 2025.

(51) Int. Cl. F04C 15/00; F04C 2/10; H05K 3/28; H05K 7/20

(52) U.S. Cl. CPC F04C 15/0096; F04C 2/10; F04C 15/008; H05K 7/20272; F04C 2240/30; F04C 2240/40; H05K 3/284

(57) ABSTRACT

A liquid pump includes a pumping mechanism configured to pump a liquid, a housing assembly housing the pumping mechanism therein while defining a wet cavity through which at least a portion of the liquid pumped by the pumping mechanism flows during operation thereof, and an electronic control unit of the liquid pump disposed within the wet cavity of the housing assembly and in fluid communication with the at least the portion of the liquid flowing therethrough. At least a portion of the electronic control unit is coated with a protective coating to prevent direct exposure of the at least the portion of the electronic control unit to the at least the portion of the liquid flowing through the wet cavity.

### CROSS-REFERENCE TO RELATED APPLICATION

This patent application claims priority to U.S. Provisional Patent Application Ser. No. 63/758,736, filed on Feb. 14, 2025, the entire disclosure of which is hereby incorporated herein by reference.

### FIELD OF THE INVENTION

The present invention relates to an electrically driven liquid pump, and more particularly, to an electric transmission oil pump having an electronic control assembly configured for operation within an oil-filled cavity of the pump.

### BACKGROUND

Electrically driven oil pumps have become increasingly important in modern powertrain systems, where they are used to circulate lubricating or hydraulic fluids in hybrid and automatic transmissions, electric axles, and other fluidic systems requiring controlled pressure and flow. A typical pump of this type employs a pumping mechanism, such as a gerotor pump, driven by an electric motor. The electric motor is, in turn, governed by an electronic control unit (ECU) or printed circuit board assembly (PCBA) that regulates operation of the corresponding pump.

In most prior-art designs, the electronic control assembly is housed in a dry cavity that is physically isolated from the lubricating oil within the pump body. The isolation is maintained by sealed housing interfaces, O-rings, or other barriers that separate the wet mechanical cavity, which contains the pumping mechanism and/or motor components, from the dry electronic cavity, which contains the PCBA and associated connectors. This configuration is intended to prevent oil from contacting sensitive electrical components and to avoid the risk of chemical degradation or electrical shorting.

Although effective in keeping the electronics dry, this approach introduces several disadvantages. The requirement for multiple sealing interfaces increases both manufacturing cost and assembly complexity. Because the PCBA is thermally isolated from the pump's working fluid, heat generated by the electronic components must be conducted through additional thermal interface materials, such as pads or pastes, to reach the housing or heat sinks thereof. This not only limits heat dissipation, but can lead to localized temperature rise, reduced efficiency, and premature component wear. The additional parts also increase the size and weight of the overall pump assembly, making packaging within a transmission housing or engine bay more difficult.

One factor driving the need for dry-cavity designs arises from the construction of common aluminum electrolytic capacitors used on the PCBA. As illustrated in FIG. 1 (Prior Art), a typical aluminum electrolytic capacitor 1 includes a metal case 2 enclosing an internal element 3 comprising rolled aluminum foil, electrolytic paper, and an electrolyte (not shown individually). The open end of the case 2 is closed by a terminal plate 4 that supports a pair of lead terminals 5 extending therethrough to provide electrical connection to the internal element 3. A rubber sealing member 6 is disposed between the terminal plate 4 and the internal element 3 within the case 2 to seal the capacitor interior. When exposed to lubricating or transmission oil, the rubber sealing member 6 can swell, soften, or otherwise degrade, allowing oil to migrate past the interface with the terminal plate 4 towards the internal element 3. Oil ingress into the interior of the capacitor can contaminate the electrolyte, corrode the aluminum foil, or cause electrical leakage and failure. Because the lead terminals 5 necessarily pass through the rubber sealing member 6, this region also presents a vulnerable point of the component when subjected to oil exposure.

This degradation mechanism presents a significant challenge for integrating the electronics directly into an oil-filled environment. Even if most circuit components are inherently oil-resistant, failure of one or more capacitors can render the entire PCBA unreliable. Consequently, prior designs have maintained strict physical separation between the oil-wetted mechanical regions of the pump and the electronic control section utilizing such components. While this strategy avoids direct exposure, it inherently limits design flexibility and adds cost and bulk to the system.

As electrified powertrains evolve toward greater integration and compactness, there is thus increasing interest in eliminating dry cavities altogether by allowing the pump motor and control electronics to share a common oil environment. Achieving this goal requires both mechanical reconfiguration of the pump housing to permit oil circulation around the electronic components and protective measures to prevent degradation of those components when exposed to oil.

Accordingly, there remains a need for electric pump systems that can operate with wet-running electronic assemblies, in which transmission oil or other working fluids may contact the PCBA, while preventing or mitigating the adverse effects of oil exposure on oil-sensitive elements such as electrolytic capacitors. Such systems would beneficially simplify construction, improve heat dissipation, and enable more compact and efficient pump assemblies without sacrificing reliability.

### SUMMARY OF THE INVENTION

In accordance with the present disclosure, an improved electric transmission oil pump having an ECU/PCBA coated with a protective coating disposed within a wet cavity thereof has surprisingly been discovered.

According to an embodiment of the present invention, a liquid pump includes a pumping mechanism configured to pump a liquid, a housing assembly housing the pumping mechanism therein while defining a wet cavity through which at least a portion of the liquid pumped by the pumping mechanism flows during operation thereof, and an electronic control unit of the liquid pump disposed within the wet cavity of the housing assembly and in fluid communication with the at least the portion of the liquid flowing therethrough. At least a portion of the electronic control unit is coated with a protective coating to prevent direct exposure of the at least the portion of the electronic control unit to the at least the portion of the liquid flowing through the wet cavity.

According to another embodiment of the present invention, a liquid pump includes a pumping mechanism configured to pump a liquid, a housing assembly housing the pumping mechanism therein and also defining a wet cavity through which at least a portion of the liquid pumped by the pumping mechanism flows during operation thereof, an electric motor assembly of the liquid pump disposed within the wet cavity of the housing assembly and in fluid communication with the at least the portion of the liquid flowing therethrough, and an electronic control unit of the liquid pump disposed within the wet cavity of the housing assembly and in fluid communication with the at least the portion of the liquid therein. The electronic control unit includes one or more electrolytic capacitors and at least a portion of each of the one or more electrolytic capacitors is coated with a protective coating to prevent exposure of an internal element of each of the one or more electrolytic capacitors to the at least the portion of the liquid flowing through the wet cavity.

### BRIEF DESCRIPTION OF THE DRAWINGS

FIG. 1 is a perspective partial cross-sectional view of an exemplary electrolytic capacitor that may be susceptible to oil degradation according to the prior art;

FIG. 2 is a perspective view of a coated electrolytic capacitor according to an embodiment of the present invention;

FIG. 3 is an elevational cross-sectional view of an electric transmission oil pump according to an embodiment of the present invention;

FIG. 4 is a front elevational view of an isolated portion of the pump of FIG. 3 showing the operation of a pumping mechanism thereof;

FIG. 5 illustrates the isolated portion of the pump of FIG. 4 with the pumping mechanism thereof removed to show a flow passageway formed through a housing segment of the pump for connecting to a wet cavity thereof;

FIG. 6 is a perspective view showing, in isolation, a PCBA coupled to the exterior of a housing segment of the pump to better illustrate a pathway for oil to flow from the interior of the housing segment to the exterior thereof having the PCBA coupled thereto; and

FIG. 7 illustrates an exemplary flow path of the oil through the pump including one possible flow pattern of the oil within the wet cavity of the pump comprising both the electrical motor components and the PCBA of the pump.

### DETAILED DESCRIPTION OF THE INVENTION

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

All documents, including patents, patent applications, and scientific literature cited in this detailed description are incorporated herein by reference, unless otherwise expressly indicated. Where any conflict or ambiguity may exist between a document incorporated by reference and this detailed description, the present detailed description controls.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, 3-9, and so on.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

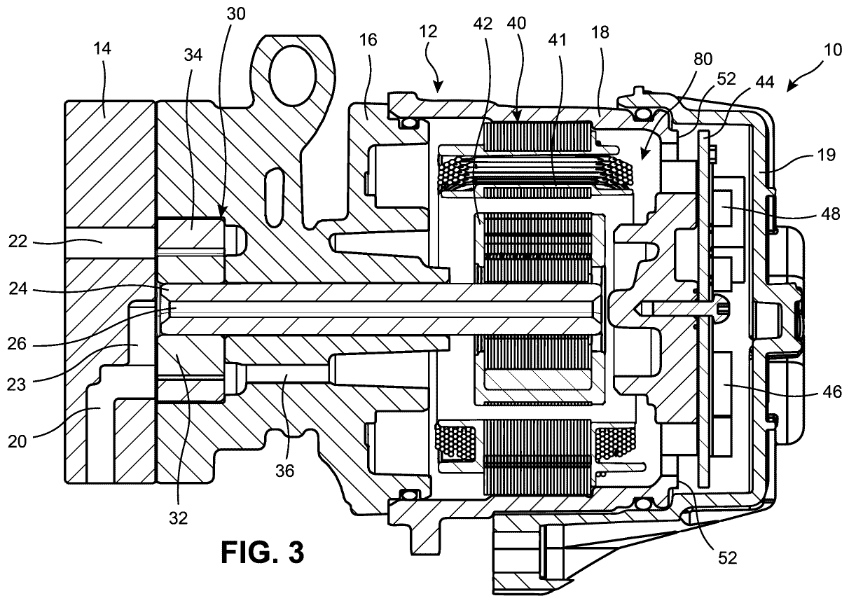

The present invention broadly includes a protective coating system for oil-exposed electrical components as well as liquid pump assemblies having such oil-exposed electrical components configured to operate in a wet environment using such protective coatings. While the illustrated pump of FIGS. 3-7 provides one suitable implementation of the invention, the coating aspect disclosed herein is likewise applicable to other pump configurations or similar devices in which electrical components are exposed to oils, lubricants, or similar working liquids while in need of lubrication, thermal regulation, or the like, as may be associated with such pumps or devices.

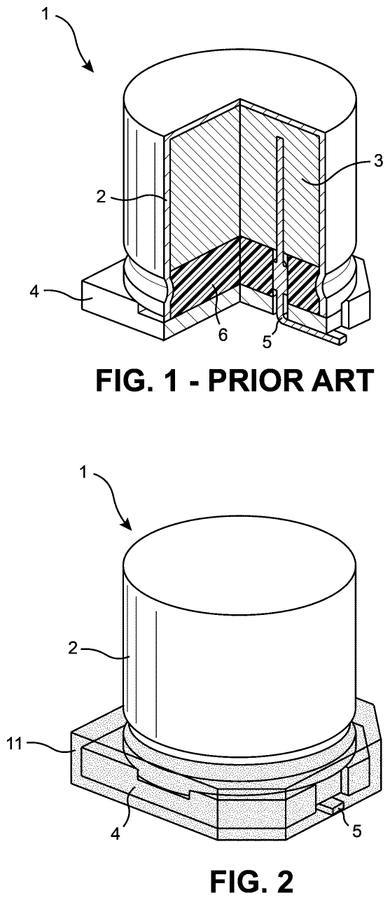

As shown in FIG. 2, which illustrates a capacitor 1 of the type previously described in connection with FIG. 1, the present invention includes the use of a protective coating 11 applied to selected regions of the capacitor 1 or the PCBA 44 (example shown in FIG. 6) to which the capacitor 1 is coupled or otherwise integrated. As explained in the background of the invention, the capacitor 1 of the type shown in FIGS. 1 and 2 may include a metal case 2, an internal element 3 comprising aluminum foil, electrolytic paper, and electrolyte, a terminal plate 4 supporting the lead terminals 5, and a rubber sealing member 6 through which the terminals 5 pass for connection to the internal element 3. As shown in FIG. 2, the protective coating 11 may be applied along those regions of the capacitor 1 including seams or interfaces that may otherwise permit entry of liquid into the internal element 3, such as along the perimeter of the rubber sealing member 6, the junction between the terminal plate 4 and the metal case 2, and a lower portion of the lead terminals 5 adjacent the sealing member 6. The thickness of the coating 11 is illustrated in exaggerated form to show the general area of coverage, and it should thus be understood that the coating may be applied as a thin conformal layer sufficient to establish an effective barrier to fluid ingress as opposed to taking on the configuration shown in FIG. 2. The coating 11 thereby protects the rubber sealing member 6 and other interface regions from exposure to chemically aggressive working fluids such as oils used in the pump environment as described in the example below. Although FIG. 2 depicts the coating applied to a single capacitor, it should be understood that one or more capacitors 48 of this type may be mounted on the PCBA 44 as shown in FIG. 6, each having localized or more extensive coatings depending on the desired degree of protection or the type of coating strategy employed with respect to the remainder of the PCBA 44, as elaborated on hereinafter.

The coating 11 may be applied to any desired electronic component or assembly intended for operation in contact with or in proximity to a liquid medium, as needed, depending on the type and composition of the corresponding electronic component or assembly. The coating serves to isolate the coated portions from the surrounding liquid, prevent absorption or chemical degradation of elastomeric seals, and maintain the electrical performance of the associated component over time. While the illustrated coating is applied to discrete regions around the capacitor 1 at which seams in need of sealing are evident, the same or similar material may be applied over the entirety of the capacitor 1, over other components such as adjacent connectors or sensors, or over a substantial portion or all of the PCBA 44. The invention is therefore not limited to any particular extent of coverage or combination of components along the PCBA 44, so long as the coating establishes the desired barrier between the associated electronic component and the surrounding liquid.

Various coating materials may be used to form the protective coating 11. Suitable families include urethane, epoxy, silicone, and acrylic conformal coatings, polymeric encapsulants, and potting compounds, alone or in combination. Such materials can incorporate fillers or coupling agents to improve adhesion, dielectric strength, and resistance to oils and hydraulic fluids. Among these, urethane-based conformal coatings have demonstrated strong chemical resistance and mechanical toughness in oil-exposed environments. Silicone and epoxy systems may be selected where higher flexibility or rigidity, respectively, is desired.

In certain embodiments, the protective coating 11 comprises a dual-cure, light-activated flexible conformal coating such as Dymax 29855. This material primarily cures under ultraviolet or visible light and includes a secondary heat-cure mechanism for shadowed regions. The dual-cure profile enables rapid processing and reliable coverage around complex geometries such as capacitor bases and connector interfaces. Dymax 29855 is flexible and vibration-tolerant, with an operational temperature capability generally up to about 150° C. and potential degradation near 165° C. under extended exposure. It can be applied by spray, brush, or automated dispensing, with a thermal post-cure following UV exposure. The coating is suitable for localized sealing (for example, capacitor base regions) or applications emphasizing cycle-time efficiency and rework access.

In other embodiments, the coating may comprise a urethane conformal coating such as HumiSeal 1A33. This solvent-borne polyurethane forms a continuous protective film after room-temperature or elevated-temperature cure and provides excellent resistance to automotive fluids, including automatic-transmission and ultra-low-viscosity oils. HumiSeal 1A33 is characterized by an operational range of approximately −40° C. to +125° C. (with short-term higher excursions), high dielectric strength, and durability suitable for harsh chemical and thermal environments. Application of the HumiSeal 1A33 may be by dip, brush, or spray. The urethane system is generally more robust for long-term oil-immersed service than light-cured flexible coatings.

Selection of the protective coating 11 may therefore be guided by service environment and manufacturing objectives. Dymax 29855 offers fast processing and flexibility with moderate long-duration oil-immersion resistance, favoring localized application and throughput, whereas HumiSeal 1A33 provides higher chemical durability and dielectric stability for continuous oil immersion. Functionally equivalent coatings exhibiting comparable adhesion, temperature capability, and oil resistance may also be employed to protect oil-exposed electronic interfaces, including capacitor-seal regions.

Proof-of-concept (“POC”) testing was conducted using modified electric-transmission oil-pump assemblies in which the usual dry cavity was opened to transmission-oil contact. Aluminum electrolytic capacitors on the tested boards were treated with Dymax 29855 at the capacitor base. These assemblies operated in automatic-transmission fluid for more than 300 hours with no issues reported during the limited test period.

The coating materials identified above were assessed for suitability across the temperature and fluid environments typical of wet-running electronic pump assemblies. Dymax 29855 maintains performance up to about 150° C. with degradation beginning near 165° C., while HumiSeal 1A33 operates within roughly −40° C. to +125° C. Both are chemically compatible with automatic-transmission and similar hydrocarbon oils under the conditions tested or expected in service.

The coating 11 need not be applied uniformly across all portions of the PCBA 44. The regions most susceptible to liquid ingress and electrical leakage are typically the interfaces between dissimilar materials, such as the junction between the capacitor terminal plate 4 and the rubber sealing member 6, and other polymer-to-metal transitions on the board. In contrast, most solid-state components, including integrated-circuit packages, transistors, resistors, and ceramic capacitors, are sufficiently encapsulated or chemically resistant that a conformal coating is not considered necessary for reliable operation in oil or other possible working liquids. These components may remain uncoated without adverse effect on electrical or mechanical performance in accordance with the present invention.

The PCBA may be manufactured with certain keep-out regions that are desirably left free of coating to prevent thermal accumulation or functional interference. Areas of high heat generation, such as power driver ICs, MOSFETs, and current-sense resistors, may experience undesirable temperature rise or outgassing if fully encapsulated and therefore may be excluded from coating coverage. Similarly, mechanical fastener openings, connector pads, electrical contact zones, and grounding points may be masked or otherwise shielded during coating application to preserve assembly tolerances and electrical continuity. These regions may be defined through temporary masking, selective dispensing, or patterned spray processes based on the board layout and coating application method.

Confining the protective coating 11 primarily to vulnerable sealing interfaces and moisture-sensitive joints minimizes material usage and curing time while maintaining protection where it is most beneficial. This selective-coating approach improves service reliability of the oil-immersed PCBA, avoids excessive thermal insulation of heat-producing components, and maintains reworkability of the assembly.

The protective coating 11 may be deposited by any suitable process that provides adequate coverage of the targeted regions while maintaining uniform layer thickness and adhesion. Examples include robotic selective dispensing, patterned spray application, dip-coating, and brush or flow application, each of which may be adapted for automated or manual production. The coating may be applied before or after assembly of the printed-circuit board, depending on whether the exposed regions are accessible in the final configuration. Localized application at the capacitor base regions may be performed prior to soldering, whereas a global conformal coating may be applied after board assembly and electrical testing.

The curing method and conditions are selected in accordance with the chemistry of the chosen coating. Urethane coatings such as HumiSeal 1A33 may be cured at room temperature or with mild heat to accelerate full film development, while dual-cure systems such as Dymax 29855 combine ultraviolet exposure with a secondary heat-cure stage to ensure polymerization in shaded regions. Epoxy and silicone coatings, where used, may be heat-assisted or air-dried in accordance with supplier recommendations. The particular parameters are not critical, provided the resulting film maintains uniform adhesion and chemical stability when exposed to the liquid passing through the pump 10.

Typical coating thicknesses may range from approximately 50 μm to 300 μm, selected according to the required barrier strength, flexibility, and dielectric properties. Multiple passes or re-coats may be used to achieve full coverage around component leads or edges. Either solvent-borne or solvent-free formulations may be applied, and curing sequence or layer count may vary to meet manufacturing and service needs, so long as the coating provides the protective function described herein.

When implemented on a PCBA 44 as shown in FIG. 6, one or more coated capacitors 48 may be positioned together with other electronic components 46 on the substrate of the board. The coating 11 may be applied either before or after the PCBA 44 is assembled to the pump 10 or other equipment. The coating may cover only individual components such as capacitors 48 or may extend over the surrounding substrate surfaces, as desired, including covering others of the electronic components 46 not constituting one of the capacitors 1, 48 as described herein. Although the coating 11 is not separately illustrated in FIG. 3, 6, or 7, it will be understood that the PCBA 44 and any components mounted thereon may include coating 11 applied in accordance with any of the variations described above with the coating 11 applied at least to any interfaces of any of the capacitors 48 considered susceptible to use with the oils described herein as working fluids for the pump 10. The presence of coating 11 is therefore implicit in those figures and descriptions, even though omitted from view for clarity.

The coated capacitor 1, 48 and coated PCBA 44 described above may be incorporated in a variety of liquid pump assemblies or other systems in which electronic components are exposed to a liquid medium in accordance with the present disclosure. One exemplary and non-limiting pump assembly 10 utilizing such coated components is illustrated in FIGS. 3-7 and will now be described for its suitability in achieving the benefits and advantages of the present invention. While the following description refers primarily to an oil pump for a vehicular transmission system, it should be appreciated that the invention is not limited to such applications and may be employed in connection with other types of liquid pumps and working fluids facing similar concerns, as desired.

The exemplary liquid pump 10 of the present disclosure generally includes a housing assembly 12 configured to define a continuous wet cavity 80 that is in fluid communication with both a pumping mechanism 30 and an electronic control assembly of the pump 10 such as the PCBA 44 of the present embodiment. The invention is not limited to the specific configuration shown, and the housing assembly 12 may be formed in any suitable manner to achieve similar fluid communication between the pumping mechanism 30 and any form of corresponding PCBA 44 or other associated electronic assembly. Likewise, while the illustrated embodiment employs a positive-displacement pumping mechanism 30, other liquid-moving mechanisms capable of establishing a suction pressure and discharge pressure to circulate a working liquid through the wet cavity 80 may be utilized without departing from the scope of the invention, and especially where such liquid-moving mechanisms are driven by associated rotation of an electric motor of the pump 10. The pump 10 of the present disclosure may be used with a variety of liquids, including lubricating oils, hydraulic fluids, or other dielectric or conductive liquids. In one exemplary application, the pump 10 is configured to circulate automatic-transmission oil.

The housing assembly 12 of the pump 10 may include one or more discrete housing segments assembled together to form the continuous wet cavity 80 and to provide fluid communication pathways between all associated components and flow spaces. In the illustrated configuration, the housing assembly 12 includes a fluid-connection segment 14, a pump-mechanism housing segment 16, a motor-housing segment 18, and an electronic housing segment 19. These segments may be formed separately and joined by fasteners, press-fit, welding, or any other suitable attachment, and may include the use of O-rings or other suitable gaskets where interfaces are formed between the various segments 14, 16, 18, 19, as needed. The modular structure of the housing allows for simplified assembly and may eliminate the need for certain prior-art features such as separate wet sleeves or intermediate dry cavities. However, it will be appreciated that alternative constructions employing a single monolithic housing or a different number of discrete or modular segments may likewise be utilized so long as the resulting structure provides a continuous wet cavity 80 in fluid communication with the pumping mechanism 30 and the electronic assembly 44 according to the present disclosure.

The fluid-connection segment 14 defines an inlet or suction flow path 20, an outlet or discharge flow path 22, and a branch passage 23 that communicates the inlet flow path 20 with a bore 26 formed axially through a drive shaft 24 of the pump 10. During operation, working liquid such as oil enters the inlet flow path 20 from an external source upstream of the pump 10, flows through the branch passage 23 and bore 26, and is distributed to the wet cavity 80 defined in part by the pump-mechanism housing segment 16, the motor-housing segment 18, and the electronic housing segment 19. The discharge flow path 22 returns the pressurized liquid from the pumping mechanism 30 to the downstream arranged portion of the fluid circuit or system in which the pump 10 is installed. The arrangement of inlet and outlet flow paths 20, 22 may be varied as needed for different applications, hence the disclosed configuration is not necessarily limiting in this respect.

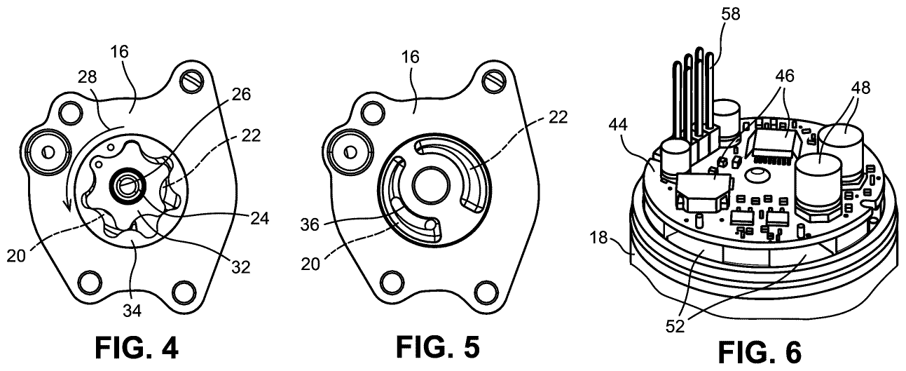

As shown in FIG. 3, the pumping mechanism housing segment 16 houses a pumping mechanism 30 which, in the present embodiment, is of the gerotor type including an inner rotor 32 and an outer rotor 34. The inner rotor 32 is driven by the shaft 24, and the relative motion of the inner and outer rotors creates successively expanding and contracting chambers between their intermeshing teeth. As the rotors rotate, expansion of the chambers along one side of the mechanism produces a suction pressure that draws liquid from the inlet flow path 20, while contraction of the chambers along the opposite side produces discharge pressure that delivers liquid to the outlet flow path 22. The direction of rotation 28 shown in FIG. 4 corresponds to this suction-and-discharge cycle, as explained in further detail hereinafter. It should be understood that other pumping mechanisms, including gear, vane, screw, crescent, or piston arrangements, may likewise be used to establish similar pressure differentials for circulating the liquid through the wet cavity 80 while remaining within the scope of the present invention.

A return passage 36 is provided through or adjacent the pumping mechanism housing segment 16 to communicate liquid from the wet cavity 80 back toward the suction side of the pumping mechanism 30 as formed on an opposing axial side of the gerotors 32, 34 relative to the inlet flow path 20, thereby allowing flow at the suction pressure on both axial sides of the pumping mechanism 30. In the illustrated embodiment, the return passage 36 allows liquid that has circulated around the motor components 41, 42 and the PCBA 44 to be drawn back by the suction pressure generated at the inlet region of the gerotor type pumping mechanism 30. The configuration of the return passage 36 may vary depending on the housing arrangement and the desired flow pattern, and multiple passages or internal channels may be used to regulate flow distribution, as desired, without departing from the scope of the present invention. For example, the return passage 36 may be provided to be partially axially extending and partially radially extending in configuration depending on the relative positioning of the associated features of the pump 10.

The motor-housing segment 18 supports an electric motor assembly 40 that includes a stator 41 fixed to the segment 18 and a rotor 42 mounted on the drive shaft 24 and disposed within the space formed by the interior of the segment 18. The motor-housing segment 18 defines a portion of the wet cavity 80 such that the stator 41, the rotor 42, and the surrounding space are in fluid communication with the working liquid circulated through the pump 10. The liquid flowing through this portion of the wet cavity 80 may serve to cool and/or lubricate the stator 41, the rotor 42, and any other associated features of the electric motor assembly 40 configured for contact with the pumped liquid during operation of the pump 10. The end of the motor-housing segment 18 is shown in FIGS. 3 and 6 as including one or more radial flow openings 52 formed therethrough which permit liquid to pass from the region of the wet cavity 80 having the motor components 41, 42 to an adjacent region disposed within the electronic housing segment 19 that contains the PCBA 44 therein. The openings 52 may be radial, axial, or oriented in any direction that allows fluid flow between the motor cavity and the region having the PCBA 44, and hence are not limited to the described radial direction. The particular number, size, and shape of openings 44 are not critical and may be varied to achieve a desired flow rate or pressure drop when encountering the PCBA 44.

The electronic housing segment 19, also referred to as a rear housing or end cap of the housing assembly 12, is coupled to an open end of the motor-housing segment 18 and defines an internal cavity for axially receiving the PCBA 44 therein. The PCBA 44 carries various electronic components 46 that control the operation of the motor and pump including one or more of the capacitors 48 of the type disclosed in FIGS. 1 and 2. The cavity defined by the electronic housing segment 19 forms a continuation of the wet cavity 80 such that liquid flowing through the openings 52 can circulate around and over the PCBA 44. An annular space 50 may be present between the outer periphery of the PCBA 44 and the inner circumferential surface of the housing segment 19 to permit circumferential or axial movement of liquid when flowing between the motor and PCBA regions of the wet cavity 80. Electrical connection to the PCBA 44 may be provided by connector terminals or prongs 58 (FIG. 6) extending through the housing wall of segment 19 to interface with external wiring. The PCBA 44 may be sealed to the housing segment 19 using any suitable gasket, adhesive, or potting material, although complete sealing is not required since the components are designed for operation in the oil environment. The surfaces of the PCBA 44 and the components 46, including capacitors 48, may be coated with the protective coating 11 described previously, thereby isolating sensitive regions from chemical attack while permitting the remainder of the assembly to be in direct contact with the liquid.

The housing assembly 12 is arranged so that the interior volumes associated with housing the pumping mechanism 30, the electric motor assembly 40, and the electronic control assembly formed by PCBA 44 together form the continuous wet cavity 80 within the pump 10. In contrast to prior-art pump constructions employing a separate dry cavity for electronics, the continuous configuration of the disclosed wet cavity 80 permits the same working liquid to circulate through all functional regions of the pump 10. This eliminates the need for intermediate isolation sleeves, secondary housings, or multiple shaft or housing segment seals previously required to separate wet and dry regions in traditional electric pump configurations. The resulting structure reduces component count, simplifies assembly, and minimizes potential leak paths.

The continuous wet cavity 80 further enhances thermal management of the pump 10 and associated components. Because the same oil or other working fluid contacts both the electric motor assembly 40 and the electronic control board 44, heat generated by the power electronics can be dissipated directly into the circulating fluid and distributed throughout the housing assembly 12. This prevents local hot-spot formation near the PCBA 44, equalizes temperature between the motor and control circuitry, and stabilizes electrical performance. In typical transmission-oil applications, this fluid circulation maintains the electronics within the desired temperature range without the need for separate heat sinks or dry-side cooling paths.

FIG. 4 illustrates an outer face of the pump-mechanism housing segment 16 facing towards the fluid-connection segment 14 and shows a direction of rotation 28 of the inner gerotor 32 and outer gerotor 34 for achieving the expanding and then contracting compression chambers of the gerotor type pumping mechanism 30 such that opposing diametric sides of the gerotors 32, 34 are associated with generating the suction pressure and the discharge pressure of the pump 10. In operation, rotation in the direction 28 causes the chambers between the inner and outer gerotors 32, 34 to expand along the suction side, drawing liquid from the inlet flow path 20, and to contract along the discharge side, forcing liquid through the outlet flow path 22. The configuration shown is exemplary only, and other gerotor geometries or pumping mechanisms may be employed to produce the same general flow of liquid.

FIG. 5 shows the same general perspective as FIG. 4 but with the gerotors 32, 34 removed to illustrate the return passage 36 formed axially through the pump-mechanism housing segment 16 and that fluidly communicates the pumping mechanism 30 with the portions of the wet cavity 80 containing the electric motor assembly 40 and the PCBA 44. The return passage 36 allows the liquid in the wet cavity 80 to flow toward the inlet side of the pump 10 under the suction generated by the pumping mechanism 30. The orientation of the return passage 36 may vary and may be formed by a drilled bore, an internal channel, or an opening between housing segments, as desired.

FIG. 6 provides an isolated perspective view of an end portion of the motor-housing segment 18 that is configured for reception within the cap-like electronic housing segment 19 of the present embodiment. The PCBA 44 is shown attached to an end face of the motor-housing segment 18, and the openings 52 formed through a circumferential wall of the housing segment 19 and extending to the interface with the PCBA 44 permit radial flow of liquid toward the annular space 50 surrounding the PCBA 44 within the housing segment 19. Liquid flowing through the openings 52 can flow radially outwardly, axially along the exterior of the PCBA 44, and then radially again along the exposed surfaces of the PCBA 44 and its components 46, 48, such as the capacitors 48, before returning again through the annular space 50 to the suction region of the pump 10 via the return passage 36.

The PCBA 44 may be mechanically secured to the motor-housing segment 18 using threaded fasteners, adhesive pads, or integrally molded standoffs. The chosen retention method may be selected to maintain a small axial and/or radial clearance around the PCBA 44 to permit unrestricted fluid circulation across both major surfaces thereof. In the illustrated embodiment, one or more fasteners extend through the PCBA 44 into threaded openings of the motor-housing segment 18, although other fastening or bonding approaches may be used, including connection to the electronic-housing segment 19.

Electrical interconnection with external control circuitry may be provided by a multi-prong connector 58 (FIG. 6) extending through the rear wall of the electronic housing segment 19. An optional O-ring or resin seal may surround the connector base to further inhibit leakage. The internal ends of the prongs may be soldered or otherwise coupled to conductive pads on the PCBA 44, and the junctions may likewise be coated with the protective coating 11 to prevent oil intrusion along the interfaces, as desired.

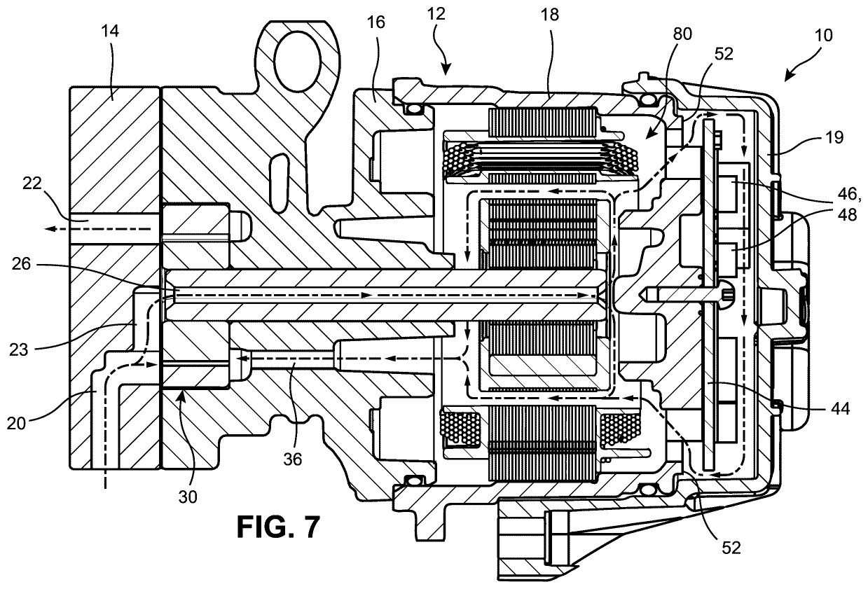

FIG. 7 illustrates one example of a possible liquid-flow pattern through the pump 10. In this example, liquid drawn into the pump through inlet flow path 20 passes through the bore 26 of the shaft 24 to the region of the wet cavity 80 having the motor rotor 42 and stator 41. A portion of the liquid may be influenced by centrifugal action of the rotating components of the motor assembly 40 to move outwardly before circulating axially and radially toward the openings 52 and over the PCBA 44. The liquid may then return again through the annular space 50 and the return passage 36 to the suction side of the pumping mechanism 30. The flow pattern shown is merely one of many possible configurations and should not be considered limiting. Other flow paths, including direct axial or circumferential circulation routes, may be employed to achieve desired cooling and lubrication of the motor and electronic components.

The circulation of liquid through the continuous wet cavity 80 serves multiple functional purposes beyond simple lubrication. The flow paths formed by the bore 26, openings 52, and return passage 36 are configured to maintain a controlled rate of liquid exchange between the motor region and the PCBA 44 region. This ensures that fresh, cooled liquid continually replaces the heated liquid adjacent the electronic components, maintaining uniform temperature and preventing local stagnation. The bore 26 and openings 52 may be dimensioned or equipped with orifices or flow restrictors to balance flow distribution and pressure within the wet cavity 80, avoiding excessive hydraulic loading on the PCBA or connectors.

In certain implementations, the liquid flow is influenced by centrifugal action of the rotating rotor 42 and shaft 24, which promote outward radial movement of the oil before it turns axially along the housing assembly 12 toward the PCBA 44. In other designs, flow may instead be driven primarily by suction pressure from the pumping mechanism 30 or by differential pressure between inlet and discharge regions. The direction of the liquid's passage, whether from the shaft 24 to the PCBA 44 or the opposite, may accordingly vary depending on the desired cooling profile and housing geometry. The invention thus encompasses both centrifugally assisted and pressure-driven flow configurations, as well as combinations thereof.

The internal channels and openings are preferably shaped to minimize vapor entrapment and dead zones, promoting even flushing of all exposed electronic surfaces. Continuous liquid turnover assists in removing particulate contaminants generated by wear or fluid degradation and prevents localized overheating of power devices on the PCBA 44. These flow features may be adjusted by modifying bore diameters, adding baffles or fins, or altering the angular position of openings 52 without departing from the underlying principles of the invention.

The described arrangement provides a pump 10 having a continuous wet cavity 80 that eliminates the need for separate dry or sealed compartments, thereby simplifying the housing design and improving thermal management by allowing the circulating liquid to contact both the electric motor assembly 40 and the electronic control assembly 44. The presence of the protective coating 11 on the PCBA 44 ensures that sensitive components, such as the capacitors 48, remain resistant to oil-induced degradation despite complete or partial immersion in the liquid. Although the illustrated embodiment shows a particular sequence of flow through the housing segments 14, 16, 18, and 19, and particular shapes and orientations of the internal passages, these details may be modified without departing from the scope of the present invention, which generally is associated with the integration of the coated electronic assembly within the continuous-cavity liquid pump structure and the resulting capability for reliable operation thereof in a fluid-immersed environment.

In view of the foregoing, it will be understood that the present invention provides both a protective coating system for oil-exposed electrical components and an integrated liquid pump assembly utilizing such coated components. The protective coating aspect of the invention affords reliable isolation of sensitive regions of electrical or electronic components, such as the sealing interfaces of electrolytic capacitors, from chemically aggressive working liquids. The coating may be applied in a variety of forms and to varying degrees of coverage, ranging from localized sealing of component bases to complete encapsulation of an entire printed-circuit-board assembly. The materials described provide strong adhesion and chemical resistance, thereby preventing deterioration of seals, electrolytes, and other elements of the coated components. The coating may be applied by conventional deposition processes and may be tailored in thickness and extent to suit particular performance and manufacturing requirements.

The liquid pump assembly aspect of the invention provides a simplified and effective arrangement for operating electrical and electronic components directly within a fluid environment. The pump housing defines a continuous wet cavity that places the pumping mechanism, electric motor, and electronic control assembly in fluid communication with one another. The circulating liquid thereby serves as a common cooling and lubricating medium, reducing temperature rise and mechanical wear while simplifying the housing structure. The elimination of separate dry cavities and sealing sleeves reduces the number of components and potential leak interfaces, improves manufacturability, and enables more compact packaging of the pump assembly.

By combining these features, the invention enables reliable long-term operation of electronic control assemblies within a liquid environment that would otherwise degrade unprotected components. The coated electronic assemblies maintain electrical integrity and mechanical stability despite direct exposure to oils and other fluids, while the integrated pump structure allows efficient fluid circulation, cooling, and lubrication of both motor and control components. The invention is adaptable to a wide range of liquid types and pump configurations, including but not limited to positive-displacement mechanisms such as gerotor, gear, vane, or screw pumps, and may be employed in various applications such as automotive transmissions, hydraulic systems, and other oil-immersed electromechanical devices.

The resulting system provides enhanced durability, reduced part count, improved thermal performance, and extended service life compared to prior arrangements requiring complex sealing or separation between wet and dry regions. It will therefore be appreciated that the present invention offers a practical and versatile approach to integrating coated electronic assemblies within liquid pump systems and similar fluid-immersed environments while maintaining the desired electrical, mechanical, and chemical reliability of all associated components.

From the foregoing description, one ordinarily skilled in the art can easily ascertain the essential characteristics of this invention and, without departing from the spirit and scope thereof, can make various changes and modifications to the invention to adapt it to various usages and conditions.

What is claimed is:

1. A liquid pump comprising:
a pumping mechanism configured to pump a liquid;
a housing assembly housing the pumping mechanism therein, the housing assembly defining a wet cavity through which at least a portion of the liquid pumped by the pumping mechanism flows during operation thereof;
an electronic control unit of the liquid pump disposed within the wet cavity of the housing assembly and in fluid communication with the at least the portion of the liquid flowing therethrough, wherein at least a portion of the electronic control unit is coated with a protective coating to prevent direct exposure of the at least the portion of the electronic control unit to the at least the portion of the liquid flowing through the wet cavity.

2. The liquid pump of claim 1, wherein the liquid is a lubricating oil.

3. The liquid pump of claim 1, wherein the liquid is transmission fluid.

4. The liquid pump of claim 1, wherein the wet cavity receives the at least the portion of the liquid prior to compression thereof in the pumping mechanism.

5. The liquid pump of claim 1, wherein the wet cavity further includes an electric motor assembly configured to drive the pumping mechanism disposed therein.

6. The liquid pump of claim 5, wherein the electric motor assembly include a stator mounted to the housing assembly and a rotor associated with driving motion of the pumping mechanism.

7. The liquid pump of claim 1, wherein the pumping mechanism comprises a gerotor pump having an inner gerotor and an outer gerotor configured to generate suction and discharge pressures on opposing diametric sides thereof.

8. The liquid pump of claim 1, wherein a drive shaft extends through the pumping mechanism and includes a bore fluidly communicating with the wet cavity.

9. The liquid pump of claim 8, wherein the bore is fluidly coupled to a branch passage formed through the housing assembly, the branch passage branching from an inlet flow path formed through the housing assembly and leading to an inlet side of the pumping mechanism.

10. The liquid pump of claim 8, wherein a return passage formed through the housing assembly provides fluid communication between the wet cavity and an inlet side of the pumping mechanism.

11. The liquid pump of claim 1, wherein the pumping mechanism receives the liquid at a suction pressure from each of the wet cavity and an inlet flow path leading to the pumping mechanism independently of the wet cavity.

12. The liquid pump of claim 1, wherein the electronic control unit comprises a printed circuit board assembly (PCBA).

13. The liquid pump of claim 12, wherein the protective coating covers a majority of the PCBA.

14. The liquid pump of claim 12, wherein the at least the portion of the electronic control unit includes one or more electrolytic capacitors coupled to the PCBA.

15. The liquid pump of claim 14, wherein the protective coating is applied along a sealing interface of each of the one or more electrolytic capacitors.

16. The liquid pump of claim 1, wherein the protective coating comprises a dual-cure light-activated conformal coating.

17. The liquid pump of claim 1, wherein the protective coating comprises a urethane conformal coating.

18. The liquid pump of claim 1, wherein the at least the portion of the liquid flowing through the wet cavity exchanges heat with the electronic control unit during operation of the liquid pump.

19. A liquid pump comprising:
a pumping mechanism configured to pump a liquid;
a housing assembly housing the pumping mechanism therein, the housing assembly defining a wet cavity through which at least a portion of the liquid pumped by the pumping mechanism flows during operation thereof;
an electric motor assembly of the liquid pump disposed within the wet cavity of the housing assembly and in fluid communication with the at least the portion of the liquid flowing therethrough; and
an electronic control unit of the liquid pump disposed within the wet cavity of the housing assembly and in fluid communication with the at least the portion of the liquid therein, the electronic control unit including one or more electrolytic capacitors, wherein at least a portion of each of the one or more electrolytic capacitors is coated with a protective coating to prevent exposure of an internal element of each of the one or more electrolytic capacitors to the at least the portion of the liquid flowing through the wet cavity.

20. The liquid pump of claim 19, wherein the housing assembly further defines each of:
an inlet flow path leading to an inlet side of the pumping mechanism;
an outlet flow path extending from an outlet side of the pumping mechanism;
a branch passage branching from the inlet flow path and directing the at least the portion of the liquid towards the wet cavity; and
a return passage leading from the wet cavity to the inlet side of the pumping mechanism.
